(19) United States
(12) Patent Application Publication
(10) Pub. No.: US 2026/0033146 A1
(43) Pub. Date: Jan. 29, 2026

(54) DISPLAY DEVICE, METHOD OF MANUFACTURING THE DISPLAY DEVICE, AND ELECTRONIC DEVICE INCLUDING THE DISPLAY DEVICE

(71) Applicant: Samsung Display Co., Ltd., Yongin-si (KR)

(72) Inventor: JAE-HOON KIM, Yongin-si (KR)

(21) Appl. No.: 19/085,645

(22) Filed: Mar. 20, 2025

(30) Foreign Application Priority Data
Jul. 25, 2024 (KR) 10-2024-0098916

(51) Int. Cl. H10K 59/122; H10K 50/115; H10K 59/12; H10K 59/80; H10K 71/13; H10K 71/60

(52) U.S. Cl. CPC H10K 59/122; H10K 50/115; H10K 59/1201; H10K 59/80515; H10K 59/873; H10K 59/879; H10K 71/13; H10K 71/60

(57) ABSTRACT

A display device includes: a first electrode located in a first pixel area, a second electrode located in a second pixel area spaced apart from the first pixel area in a plan view, a first partition wall layer located on the first electrode and defining a first opening in the first pixel area and a second opening in the second pixel area, a first intermediate layer located in the first opening and including an inorganic light emitting material, a third electrode located on the first intermediate layer in the first opening, a resin layer located on the third electrode in the first opening, a second intermediate layer located in the second opening and including an organic light emitting material, and a fourth electrode located on the second intermediate layer in the second opening.

### CROSS-REFERENCE TO RELATED APPLICATION

The present application claims priority to and benefit of Korean Patent Application No. 10-2024-0098916, filed on Jul. 25, 2024, in the Korean Intellectual Property Office, the entire content of which is incorporated herein by reference.

### BACKGROUND

### 1. Field

One or more aspects of embodiments of the present disclosure relate to a display device, a method of manufacturing the display device, and an electronic device including the display device. For example, embodiments of the present disclosure relate to a display device providing visual information, and a method of manufacturing the display device, and an electronic device including the display device.

### 2. Description of the Related Art

A display device is a device that displays an image to provide visual information to a user. Among display devices, an organic light emitting diode display device may be utilized as a display device and has attracted recent attention.

There is ongoing research of a display device having a hybrid structure including an organic light emitting element and a quantum dot light emitting element at the same time (e.g., concurrently). The quantum dot light emitting element has advantages of having high (suitably high) chromaticity, high (suitably high) luminous efficiency, and/or multicolorization.

### SUMMARY

One or more aspects of embodiments of the present disclosure provide a display device having improved quality.

One or more embodiments provide a method of manufacturing the display device.

One or more embodiments provide an electronic device including the display device.

A display device according to one or more embodiments includes a first electrode located in a first pixel area, a second electrode located in a second pixel area spaced apart from the first pixel area in a plan view, a first partition wall layer located on the first electrode and defining a first opening in the first pixel area and a second opening in the second pixel area, a first intermediate layer located in the first opening and including an inorganic light emitting material, a third electrode located on the first intermediate layer in the first opening, a resin layer located on the third electrode in the first opening, a second intermediate layer located in the second opening and including an organic light emitting material, and a fourth electrode located on the second intermediate layer in the second opening.

In one or more embodiments, the resin layer may be spaced apart from the second pixel area in the plan view.

In one or more embodiments, the second intermediate layer may be to emit blue light.

In one or more embodiments, the first intermediate layer may include a first hole transport area, a first light emitting layer located on the first hole transport area and including an inorganic light emitting material, and a first electron transport area located on the first light emitting layer.

In one or more embodiments, the second intermediate layer may include a second hole transport area, a second light emitting layer located on the second hole transport area and including an organic light emitting material, and a second electron transport area located on the second light emitting layer.

In one or more embodiments, the display device may further include an encapsulation layer covering at least a portion of each of the resin layer and the fourth electrode.

In one or more embodiments, the display device may further include a second partition wall layer located on the first partition wall layer and including a first tip protruding from an upper surface of the first partition wall layer toward a center of the first opening.

In one or more embodiments, the second partition wall layer may further include a second tip protruding from the upper surface of the first partition wall layer toward a center of the second opening.

In one or more embodiments, the resin layer may contact the first tip.

In one or more embodiments, the resin layer may include an active component including an acid.

In one or more embodiments, the display device may further include a step compensation layer located on the fourth electrode in the second opening.

In one or more embodiments, the display device may further include a first lens layer covering the resin layer and a second lens layer covering the step compensation layer.

In one or more embodiments, the first partition wall layer may include a metal.

A method of manufacturing a display device according to one or more embodiments includes forming a first electrode in a first pixel area, forming a second electrode in a second pixel area spaced apart from the first pixel area in a plan view, forming a first partition wall layer defining a first opening in the first pixel area and a second opening in the second pixel area on the first electrode, forming a first intermediate layer including an inorganic light emitting material in the first opening, forming a third electrode on the first intermediate layer in the first opening, forming a resin layer on the third electrode in the first opening, forming a second intermediate layer including an organic light emitting material in the second opening, and forming a fourth electrode on the second intermediate layer in the second opening.

In one or more embodiments, the forming of the first partition wall layer may include forming a first preliminary partition wall layer on the first electrode and forming the first opening and the second opening in the first preliminary partition wall layer through a wet etching process.

In one or more embodiments, the method may further include forming a second preliminary partition wall layer on the first preliminary partition wall layer after the forming of the first preliminary partition wall layer, before the forming of the first opening and the second opening.

In one or more embodiments, the method may further include forming a third opening in the second preliminary partition wall layer in the first pixel area and a fourth opening in the second preliminary partition wall layer in the second pixel area through a dry etching process after the forming of the second preliminary partition wall layer, before the forming of the first opening and the second opening.

In one or more embodiments, the resin layer may be formed to be spaced apart from the second opening in the plan view.

In one or more embodiments, each of the first intermediate layer, the second intermediate layer, and the resin layer may be formed through an inkjet printing process.

An electronic device according to one or more embodiments includes a first electrode located in a first pixel area, a second electrode located in a second pixel area spaced apart from the first pixel area in a plan view, a first partition wall layer located on the first electrode and defining a first opening in the first pixel area and a second opening in the second pixel area, a first intermediate layer located in the first opening and including an inorganic light emitting material, a third electrode located on the first intermediate layer in the first opening, a resin layer located on the third electrode in the first opening, a second intermediate layer located in the second opening and including an organic light emitting material, a fourth electrode located on the second intermediate layer in the second opening, and a memory configured to store data information.

A display device according to one or more embodiments may be a display device of a hybrid structure including an organic light emitting element and a quantum dot light emitting element at same time (e.g., concurrently). In one or more embodiments, the display device may include a resin layer including an active component. The active component may promote a positive aging effect (e.g., aspect) of the quantum dot light emitting element. However, when the active component is diffused into the organic light emitting element, characteristics of the organic light emitting element may be deteriorated, unlike those of the quantum dot light emitting element.

According to one or more embodiments, the resin layer may selectively overlap the quantum dot light emitting element in a plan view, and may be spaced apart from the organic light emitting element in the plan view by a partition wall layer. Accordingly, the active component may be selectively diffused from the resin layer to the quantum dot light emitting element. For example, the active component may not affect (or may not substantially affect) the organic light emitting element. Accordingly, the positive aging effect (e.g., aspect) of the quantum dot light emitting element may be promoted, and a characteristic degradation of the organic light emitting element may be prevented or reduced.

### BRIEF DESCRIPTION OF THE DRAWINGS

Illustrative, non-limiting embodiments will be more clearly understood from the following detailed description in conjunction with the accompanying drawings, in which:

FIG. 1 is a plan view illustrating a display device according to one or more embodiments.

FIG. 2 is a cross-sectional view illustrating an example of the display device of FIG. 1 taken along the line I-I′.

FIG. 3A is a cross-sectional view schematically illustrating a first intermediate layer of FIG. 2.

FIG. 3B is a cross-sectional view schematically illustrating a second intermediate layer of FIG. 2.

FIG. 3C is a cross-sectional view schematically illustrating a third intermediate layer of FIG. 2.

FIGS. 4, 5, 6, 7, 8, 9, 10, and 11 are cross-sectional views illustrating a method of manufacturing the display device of FIG. 2.

FIG. 12 is a cross-sectional view illustrating a display device according to one or more embodiments.

FIG. 13 is a block diagram illustrating an electronic device according to one or more embodiments.

FIG. 14 is a schematic diagram of an electronic device according to one or more embodiments.

### DETAILED DESCRIPTION

Hereinafter, display device in accordance with embodiments will be described in more detail with reference to the accompanying drawings. The same reference numerals are used for the same components in the drawings, and redundant descriptions of the same components will not be provided.

It will be understood that, although the terms first, second, etc. may be used herein to describe various elements, these elements should not be limited by these terms. These terms are only used to distinguish one element from another element. Thus, a first element could be termed a second element without departing from the teachings of the present invention. Similarly, a second element could be termed a first element.

As used herein, the singular forms “a,” “an,” and “the” are intended to include the plural forms as well, unless the context clearly indicates otherwise.

It will be further understood that the terms “includes,” “including,” “comprises,” and/or “comprising,” when used in this specification, specify the presence of stated features, steps, operations, elements, and/or components, but do not preclude the presence or addition of one or more other features, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As used herein, the terms “use,” “using,” and “used” may be considered synonymous with the terms “utilize,” “utilizing,” and “utilized,” respectively.

As used herein, expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As used herein, the term “and/or” includes any and all combinations of one or more of the associated listed items.

Further, the use of “may” when describing embodiments of the present disclosure refers to “one or more embodiments of the present disclosure”.

It will be understood that when an element is referred to as being “on,” “connected to,” or “coupled to” another element, it may be directly on, connected, or coupled to the other element or one or more intervening elements may also be present. When an element is referred to as being “directly on,” “directly connected to,” or “directly coupled to” another element, there are no intervening elements present.

Spatially relative terms, such as “beneath,” “below,” “lower,” “above,” “upper,” “bottom,” “top” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic device and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art would appreciate, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

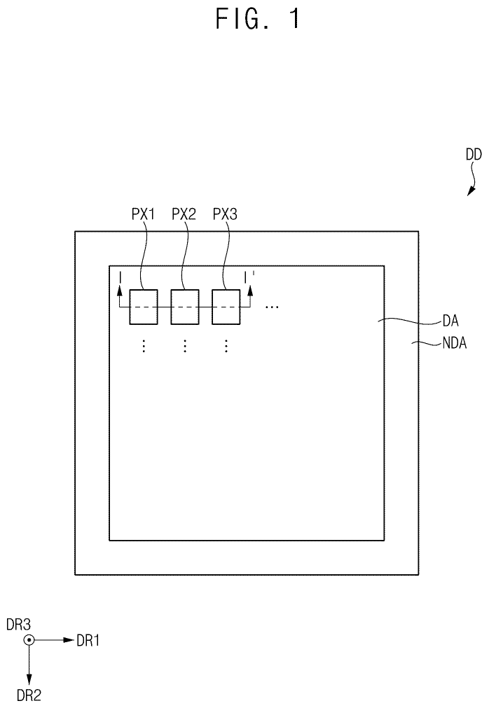

FIG. 1 is a plan view illustrating a display device according to one or more embodiments.

Referring to FIG. 1, a display device DD according to one or more embodiments may include a display area DA and a non-display area NDA.

The display area DA may be an area that generates light and/or adjusts a transmittance of light provided from an external light source to display an image. A plurality of pixel areas may be located in the display area DA. For example, a first pixel area PX1, a second pixel area PX2, and a third pixel area PX3 may be located in the display area DA. Each of the plurality of pixel areas may be to emit light. For example, the first pixel area PX1 may be to emit a first light, the second pixel area PX2 may be to emit a second light, and the third pixel area PX3 may be to emit a third light. In one or more embodiments, the first light may be red light, the second light may be green light, and the third light may be blue light. However, this disclosure is not limited thereto. For example, the first pixel area PX1, the second pixel area PX2, and the third pixel area PX3 may be combined to emit yellow, cyan, and/or magenta light.

The plurality of pixel areas may be located over the entire display area DA. Accordingly, the display area DA may display an image. In one or more embodiments, the plurality of pixel areas may be repeatedly arranged along a first direction DR1 and a second direction DR2 crossing the first direction DR1. For example, the second pixel area PX2 may be spaced apart from the first pixel area PX1 in the first direction DR1. The third pixel area PX3 may be spaced apart from the second pixel area PX2 in the first direction DR1.

The non-display area NDA may surround at least a portion of the display area DA. A driver may be located in the non-display area NDA. The driver may provide a signal or a voltage to the plurality of pixel areas. For example, the driver may include a data driver, a gate driver, and/or the like. The non-display area NDA may not display an image.

In one or more embodiments, the first direction DR1 and the second direction DR2 crossing the first direction DR1 may be defined. For example, the second direction DR2 may be substantially perpendicular to the first direction DR1. However, this disclosure is not limited thereto, and the second direction DR2 may form an acute angle or an obtuse angle with the first direction DR1. In one or more embodiments, a third direction DR3 crossing a plane formed by the first direction DR1 and the second direction DR2 may be defined. For example, the third direction DR3 may be substantially perpendicular to the plane formed by the first direction DR1 and the second directions DR2. However, this disclosure is not limited thereto, and the third direction DR3 may form an acute angle or an obtuse angle with the plane formed by the first direction DR1 and the second direction DR2.

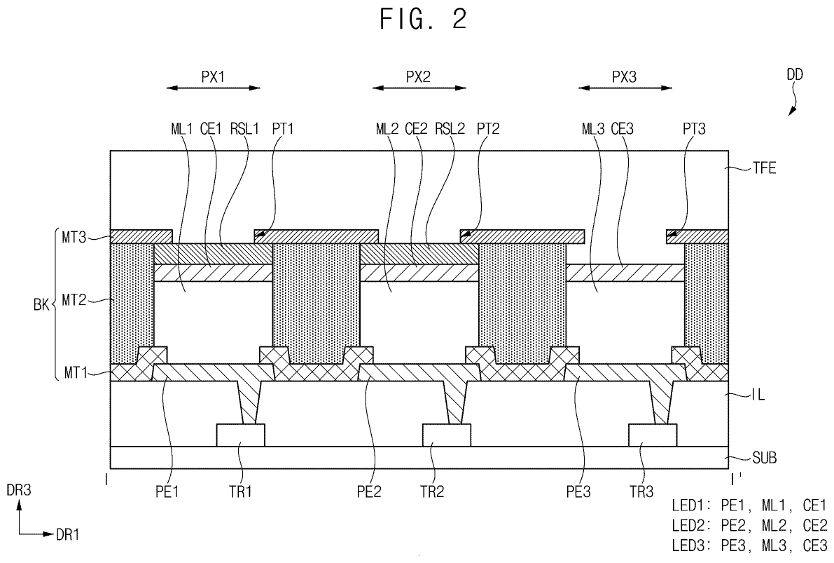

FIG. 2 is a cross-sectional view illustrating an example of the display device of FIG. 1 taken along the line I-I′.

Referring to FIGS. 1 and 2, the display device DD according to one or more embodiments may include a substrate SUB, an insulating structure IL, a first transistor TR1, a second transistor TR2, a third transistor TR3, a first light emitting element LED1, a second light emitting element LED2, a third light emitting element LED3, a first resin layer RSL1, a second resin layer RSL2, a bank layer BK, and an encapsulation layer TFE.

The first light emitting element LED1 may include a first pixel electrode PE1, a first intermediate layer ML1, and a first common electrode CE1. The second light emitting element LED2 may include a second pixel electrode PE2, a second intermediate layer ML2, and a second common electrode CE2. The third light emitting element LED3 may include a third pixel electrode PE3, a third intermediate layer ML3, and a third common electrode CE3.

The substrate SUB may be a base of the display device DD. The substrate SUB may include a transparent material and/or an opaque material. The substrate SUB may be formed of a transparent resin substrate. Example of the transparent resin substrate may include a polyimide substrate. For example, the polyimide substrate may include a first organic layer, a first barrier layer, a second organic layer, and/or the like. In some embodiments, the substrate SUB may optionally include a quartz substrate (e.g. a synthetic quartz substrate and/or a fluorine-doped quartz substrate), a calcium fluoride substrate, a sodalime glass substrate, a non-alkali glass substrate, and/or the like. These materials may be used alone or in combination with each other.

The first transistor TR1, the second transistor TR2, and the third transistor TR3 may be located on the substrate SUB. For example, the first transistor TR1, the second transistor TR2, and the third transistor TR3 may be located in the display area DA on the substrate SUB. For example, each of the first transistor TR1, the second transistor TR2, and the third transistor TR3 may include amorphous silicon, polycrystalline silicon, and/or a metal oxide semiconductor. The metal oxide semiconductor may include a binary compound (“ABₓ”), a ternary compound (“ABₓC_{y}”), a quaternary compound (“ABₓC_{y}D_{z}”), and/or the like including indium (“In”), zinc (“Zn”), gallium (“Ga”), tin (“Sn”), titanium (“Ti”), aluminum (“Al”), hafnium (“Hf”), zirconium (“Zr”), magnesium (“Mg”), and/or the like. These materials may be used alone or in combination with each other. The metal oxide semiconductor may include zinc oxide (“ZnOₓ”), gallium oxide (“GaOₓ”), tin oxide (“SnOₓ”), indium oxide (“InOₓ”), indium gallium oxide (“IGO”), indium zinc oxide (“IZO”), indium tin oxide (“ITO”), indium zinc tin oxide (“IZTO”), and/or indium gallium zinc oxide (“IGZO”). These materials may be used alone or in combination with each other.

The insulating structure IL may be located on the substrate SUB. The insulating structure IL may cover the first transistor TR1, the second transistor TR2, and the third transistor TR3. In one or more embodiments, the insulating structure IL may include at least one inorganic insulating layer and at least one organic insulating layer. For example, the inorganic insulating layer may include silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other. The organic insulating layer may include photoresist, polyacryl-based resin, polyimide-based resin, polyamide-based resin, siloxane-based resin, acrylic-based resin, epoxy-based resin, and/or the like. These materials may be used alone or in combination with each other. However, this disclosure is not limited thereto, and in one or more other embodiments, the insulating structure IL may include only an inorganic insulating layer.

The first pixel electrode PE1, the second pixel electrode PE2, and the third pixel electrode PE3 may be located on the insulating structure IL. For example, the first pixel electrode PE1 may be located in the first pixel area PX1, the second pixel electrode PE2 may be located in the second pixel area PX2, and the third pixel electrode PE3 may be located in the third pixel area PX3. The first pixel electrode PE1 may be connected to the first transistor TR1 through a first contact hole formed by removing a portion of the insulating structure IL. The second pixel electrode PE2 may be connected to the second transistor TR2 through a second contact hole formed by removing a portion of the insulating structure IL. The third pixel electrode PE3 may be connected to the third transistor TR3 through a third contact hole formed by removing a portion of the insulating structure IL. For example, each of the first pixel electrode PE1, the second pixel electrode PE2, and the third pixel electrode PE3 may include a metal, an alloy, a metal nitride, a conductive metal oxide, a transparent conductive material, and/or the like. These materials may be used alone or in combination. For example, the first pixel electrode PE1 may operate as an anode of the first light emitting element LED1, the second pixel electrode PE2 may operate as an anode of the second light emitting element LED2, and the third pixel electrode PE3 may operate as an anode of the third light emitting element LED3. For example, each of the first pixel electrode PE1 and the second pixel electrode PE2 may be referred to as a first electrode. In one or more embodiments, the third pixel electrode PE3 may be referred to as a second electrode.

The bank layer BK may be located on the insulating structure IL. The bank layer BK may include a first partition wall layer MT1, a second partition wall layer MT2, and a third partition wall layer MT3. The first partition wall layer MT1, the second partition wall layer MT2, and the third partition wall layer MT3 may be sequentially stacked in the third direction DR3.

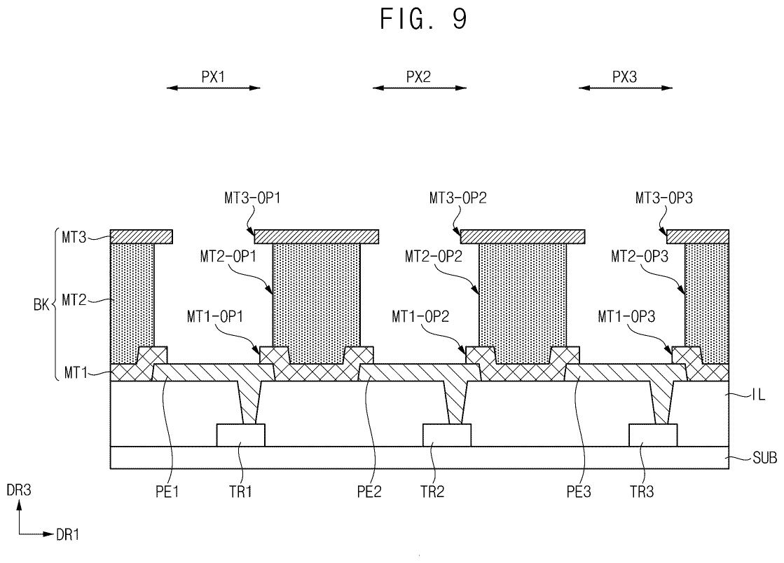

The first partition wall layer MT1 may cover at least a portion of each of the first pixel electrode PE1, the second pixel electrode PE2, and the third pixel electrode PE3. The first partition wall layer MT1 may define a first opening (e.g., a first opening MT1-OP1 of FIG. 9) in the first pixel area PX1. The first opening of the first partition wall layer MT1 may expose at least a portion of the first pixel electrode PE1. In one or more embodiments, the first partition wall layer MT1 may define a second opening (e.g., a second opening MT1-OP2 of FIG. 9) in the second pixel area PX2. The second opening of the first partition wall layer MT1 may expose at least a portion of the second pixel electrode PE2. In one or more embodiments, the first partition wall layer MT1 may define a third opening (e.g., a third opening MT1-OP3 of FIG. 9) in the third pixel area PX3. The third opening of the first partition wall layer MT1 may expose at least a portion of the third pixel electrode PE3.

The second partition wall layer MT2 may be located on the first partition wall layer MT1. For example, the second partition wall layer MT2 may cover at least a portion of the first partition wall layer MT1. The second partition wall layer MT2 may define a first opening (e.g., a first opening MT2-OP1 of FIG. 9) in the first pixel area PX1. The first opening of the second partition wall layer MT2 may at least partially overlap the first opening of the first partition wall layer MT1 in a plan view. For example, the first opening of the second partition wall layer MT2 may be spatially connected to the first opening of the first partition wall layer MT1. In one or more embodiments, the second partition wall layer MT2 may define a second opening (e.g., a second opening MT2-OP2 of FIG. 9) in the second pixel area PX2. The second opening of the second partition wall layer MT2 may at least partially overlap the second opening of the first partition wall layer MT1 in the plan view. For example, the second opening of the second partition wall layer MT2 may be spatially connected to the second opening of the first partition wall layer MT1. In one or more embodiments, the second partition wall layer MT2 may define a third opening (e.g., a third opening MT2-OP3 of FIG. 9) in the third pixel area PX3. The third opening of the second partition wall layer MT2 may at least partially overlap the third opening of the first partition wall layer MT1 in the plan view. For example, the third opening of the second partition wall layer MT2 may be spatially connected to the third opening of the first partition wall layer MT1.

The third partition wall layer MT3 may be located on the second partition wall layer MT2. For example, the third partition wall layer MT3 may cover at least a portion of the second partition wall layer MT2. The third partition wall layer MT3 may define a first opening (e.g., a first opening MT3-OP1 of FIG. 9) in the first pixel area PX1. The first opening of the third partition wall layer MT3 may at least partially overlap the first opening of the second partition wall layer MT2 in the plan view. For example, the first opening of the third partition wall layer MT3 may be spatially connected to the first opening of the second partition wall layer MT2. In one or more embodiments, the third partition wall layer MT3 may define a second opening (e.g., a second opening MT3-OP2 of FIG. 9) in the second pixel area PX2. The second opening of the third partition wall layer MT3 may at least partially overlap the second opening of the second partition wall layer MT2 in the plan view. For example, the second opening of the third partition wall layer MT3 may be spatially connected to the second opening of the second partition wall layer MT2. In one or more embodiments, the third partition wall layer MT3 may define a third opening (e.g., a third opening MT3-OP3 of FIG. 9) in the third pixel area PX3. The third opening of the third partition wall layer MT3 may at least partially overlap the third opening of the second partition wall layer MT2 in the plan view. For example, the third opening of the third partition wall layer MT3 may be spatially connected to the third opening of the second partition wall layer MT2.

In one or more embodiments, the third partition wall layer MT3 may include a first tip PT1 protruding from an upper surface of the second partition wall layer MT2 toward a center of the first opening of the second partition wall layer MT2. For example, the third partition wall layer MT3 may include the first tip PT1 protruding from the upper surface of the second partition wall layer MT2 toward a center of the first pixel area PX1. For example, a width of the first opening of the third partition wall layer MT3 in the first direction DR1 may be less than a width of the first opening of the second partition wall layer MT2 in the first direction DR1.

The third partition wall layer MT3 may include a second tip PT2 protruding from the upper surface of the second partition wall layer MT2 toward a center of the second opening of the second partition wall layer MT2. For example, the third partition wall layer MT3 may include the second tip PT2 protruding from the upper surface of the second partition wall layer MT2 toward a center of the second pixel area PX2. For example, a width of the second opening of the third partition wall layer MT3 in the first direction DR1 may be less than a width of the second opening of the second partition wall layer MT2 in the first direction DR1.

The third partition wall layer MT3 may include a third tip PT3 protruding from the upper surface of the second partition wall layer MT2 toward a center of the third opening of the second partition wall layer MT2. For example, the third partition wall layer MT3 may include the third tip PT3 protruding from the upper surface of the second partition wall layer MT2 toward a center of the third pixel area PX3. For example, a width of the third opening of the third partition wall layer MT3 in the first direction DR1 may be less than a width of the third opening of the second partition wall layer MT2 in the first direction DR1.

The first opening of the first partition wall layer MT1, the first opening of the second partition wall layer MT2, and the first opening of the third partition wall layer MT3 may be connected to each other to form a first through-hole exposing at least a portion of the first pixel electrode PE1. The second opening of the first partition wall layer MT1, the second opening of the second partition wall layer MT2, and the second opening of the third partition wall layer MT3 may be connected to each other to form a second through-hole exposing at least a portion of the second pixel electrode PE2. The third opening of the first partition wall layer MT1, the third opening of the second partition wall layer MT2, and the third opening of the third partition wall layer MT3 may be connected to each other to form a third-through hole exposing at least a portion of the third pixel electrode PE3.

In one or more embodiments, each of the first partition wall layer MT1, the second partition wall layer MT2, and the third partition wall layer MT3 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. In one or more embodiments, examples of the metal nitride may include aluminum nitride (“AlNₓ”), tungsten nitride (“WNₓ”), chromium nitride (“CrNₓ”), and/or the like. These materials may be used alone or in combination with each other. For example, each of the first partition wall layer MT1 and the third partition wall layer MT3 may include titanium (“Ti”), and the second partition wall layer MT2 may include aluminum (“Al”).

However, this disclosure is not limited thereto, and in other embodiments, each of the first partition wall layer MT1, the second partition wall layer MT2, and the third partition wall layer MT3 may include an inorganic material and/or an organic material. For example, each of the first partition wall layer MT1 and the third partition wall layer MT3 may include an inorganic material, and the second partition wall layer MT2 may include an organic material.

The first intermediate layer ML1 may be located on the first pixel electrode PE1. The first intermediate layer ML1 may be located in at least a portion of the first through-hole. For example, the first intermediate layer ML1 may be located in a portion of the first opening of the second partition wall layer MT2 and in the first opening of the first partition wall layer MT1. For example, the first intermediate layer ML1 may be located in the first pixel area PX1.

The second intermediate layer ML2 may be located on the second pixel electrode PE2. The second intermediate layer ML2 may be located in at least a portion of the second through-hole. For example, the second intermediate layer ML2 may be located in a portion of the second opening of the second partition wall layer MT2 and in the second opening of the first partition wall layer MT1. For example, the second intermediate layer ML2 may be located in the second pixel area PX2.

The third intermediate layer ML3 may be located on the third pixel electrode PE3. The third intermediate layer ML3 may be located in at least a portion of the third through-hole. For example, the third intermediate layer ML3 may be located in a portion of the third opening of the second partition wall layer MT2 and in the third opening of the first partition wall layer MT1. For example, the third intermediate layer ML3 may be located in the third pixel area PX3.

The first intermediate layer ML1 may include a material that is to emit the first light, the second intermediate layer ML2 may include a material that is to emit the second light, and the third intermediate layer ML3 may include a material that is to emit the third light. As described above, the first light may be red light, the second light may be green light, and the third light may be blue light. However, this disclosure is not limited thereto.

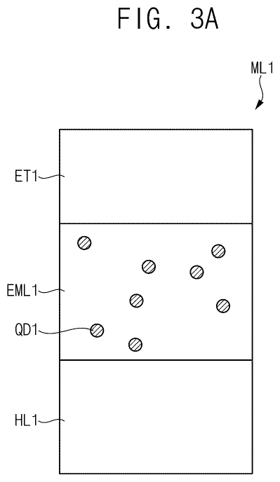

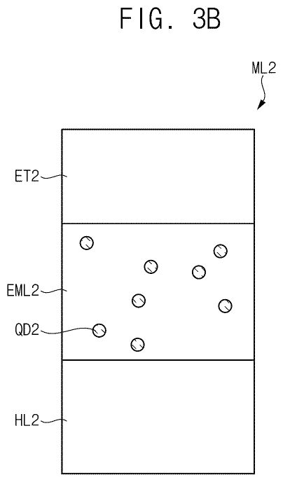

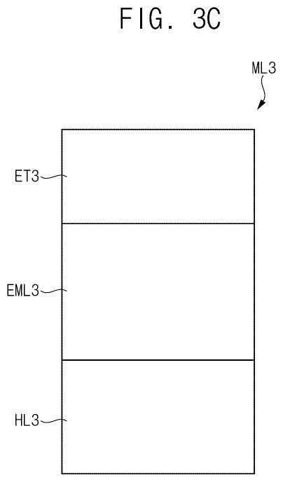

FIG. 3A is a cross-sectional view schematically illustrating a first intermediate layer of FIG. 2. FIG. 3B is a cross-sectional view schematically illustrating a second intermediate layer of FIG. 2. FIG. 3C is a cross-sectional view schematically illustrating a third intermediate layer of FIG. 2.

Referring further to FIG. 3A, FIG. 3B, and FIG. 3C, as illustrated in FIG. 3A, the first intermediate layer ML1 may include a first hole transport area HL1, a first light emitting layer EML1, and a first electron transport area ET1, which are sequentially stacked in the third direction DR3. As illustrated in FIG. 3B, the second intermediate layer ML2 may include a second hole transport area HL2, a second light emitting layer EML2, and a second electron transport area ET2, which are sequentially stacked in the third direction DR3. As illustrated in FIG. 3C, the third intermediate layer ML3 may include a third hole transport area HL3, a third light emitting layer EML3, and a third electron transport area ET3, which are sequentially stacked in the third direction DR3.

Each of the first hole transport area HL1, the second hole transport area HL2, and the third hole transport area HL3 may have i) a single layer structure made of a single material, ii) a single layer structure made of a plurality of different materials, or iii) a multi-layer structure made of a plurality of different materials.

Each of the first hole transport area HL1, the second hole transport area HL2, and the third hole transport area HL3 may include at least one layer selected from among a hole injection layer, a hole transport layer, a sub light emitting layer, and an electron blocking layer.

In one or more embodiments, the first hole transport area HL1, the second hole transport area HL2, and the third hole transport area HL3 may each independently have a single layer structure formed of a plurality of different materials. In some embodiments, the first hole transport area HL1, the second hole transport area HL2, and the third hole transport area HL3 may each independently have a multi-layer structure. For example, the first hole transport area HL1, the second hole transport area HL2, and the third hole transport area HL3 may each independently have a multilayer structure of a hole injection layer/hole transport layer, a hole injection layer/a hole transport layer/a sub light emitting layer, a hole injection layer/a sub light emitting layer, a hole transport layer/a sub light emitting layer, or a hole injection layer/a hole transport layer/a electron blocking layer. However, this disclosure is not limited thereto.

The first hole transport area HL1, the second hole transport area HL2, and the third hole transport area HL3 may each independently include an amorphous inorganic material and/or an organic material. The sub light emitting layer may compensate for an optical resonance distance according to wavelength of light emitted from the first light emitting layer EML1, the second light emitting layer EML2, and/or the third light emitting layer EML3, thereby increasing light emitting efficiency. In one or more embodiments, the electron blocking layer may prevent or reduce injection of electrons from the first electron transport area ET1, the second electron transport area ET2, and/or the third electron transport area ET3.

Each of the first light emitting layer EML1, the second light emitting layer EML2, and the third light emitting layer EML3 may include a material that is to emit light. For example, the first light emitting layer EML1 may include a material that is to emit the first light, the second light emitting layer EML2 may include a material that is to emit the second light, and the third light emitting layer EML3 may include a material that is to emit the third light. As described above, the first light may be red light, the second light may be green light, and the third light may be blue light. However, this disclosure is not limited thereto.

In one or more embodiments, the first light emitting layer EML1 may include an inorganic light emitting material. For example, the inorganic light emitting material included in the first light emitting layer EML1 may include a first quantum dot QD1. For example, the first light emitting element LED1 may be a quantum dot light emitting element.

In one or more embodiments, the second light emitting layer EML2 may include an inorganic light emitting material. For example, the inorganic light emitting material included in the second light emitting layer EML2 may include a second quantum dot QD2. For example, the second light emitting element LED2 may be a quantum dot light emitting element.

In one or more embodiments, the third light emitting layer EML3 may include an organic light emitting material. For example, the third light emitting element LED3 may be an organic light emitting element. The organic light emitting material may include a low-molecular-weight organic compound and/or a high-molecular-weight organic compound. Examples of the low-molecular-weight organic compound may include copper phthalocyanine, N,N-diphenylbenzidine, tris-(8-hydroxyquinoline)aluminum, and/or the like. These materials may be used alone or in combination with each other. Examples of the high-molecular-weight organic compound may include poly(3,4-ethylenedioxythiophene), polyaniline, polyphenylenevinylene, polyfluorene, and/or the like. These materials may be used alone or in combination with each other.

For example, the display device DD may be a display device having a hybrid structure including an organic light emitting element and a quantum dot light emitting element at same time (or concurrently).

Each of the first quantum dot QD1 and the second quantum dot QD2 may be to emit light by (e.g., in response to) stimulation by light. For example, the first quantum dot QD1 and the second quantum dot QD2 may each independently include an II-VI group semiconductor compound, an III-VI group semiconductor compound, an III-V group semiconductor compound, an IV-VI group semiconductor compound, an IV group element, a compound including the IV group element, an I-III-VI group semiconductor compound, and/or the like. These materials may be used alone or in combination with each other.

The II-VI group semiconductor compound may include a binary compound such as CdS, CdSe, CdTe, ZnS, ZnSe, ZnTe, ZnO, HgS, HgSe, HgTe, MgS, MgSe, and/or the like; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe MgZnS, MgZnSe, and/or the like; a quaternary compounds such as CdZnSeS, CdZnSeTe, CdZnSTe, CdHgSeS, CdHgSeTe, CdHgSTe, HgZnSeS, HgZnSeTe, HgZnSTe, and/or the like; and/or any combination of the above compounds.

The III-VI group semiconductor compound may include a binary compound such as In₂S₃, Ga₂S₃, and/or the like; a ternary compound such as InGaS₃, InGaSe₃ and/or the like; and/or any combination of the above compounds.

The III-V group semiconductor compound may include a binary compound such as GaN, GaP, GaAs, GaSb, AlN, AlP, AlAs, AlSb, InN, InP, InAs, InSb, and/or the like; a ternary compound such as GaNP, GaNAs, GaNSb, GaPAs, GaPSb, AlNP, AlNAs, AlNSb, AlPAS, AlPSb, InAsP, InGaP, InGaAs, InAlP, InNP, InNAs, InNSb, InPAs, InPSb, GaAlNP, and/or the like; a quaternary compound such as GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and/or the like; and/or any combination of the above compounds.

The IV-VI group semiconductor compound may include a binary compound such as SnS, SnSe, SnTe, PbS, PbSe, PbTe, and/or the like; a ternary compound such as SnSeS, SnSeTe, SnSTe, PbSeS, PbSeTe, PbSTe, SnPbS, SnPbSe, SnPbTe, and/or the like; a quaternary compound such as SnPbSSe, SnPbSeTe, SnPbSTe, and/or the like; and/or any combination of the above compounds.

The IV group element and the compound including the IV group element may include a binary compound such as Si and/or Ge, a binary compound such as SiC, SiGe, and/or the like; and/or any combination of the above compounds.

The I-III-VI group semiconductor compound may include a ternary compound such as AgInS, AgInS₂, CuInS, CuInS₂, CuGaO₂, AgGaO₂, AgAlO₂, and/or the like; and/or any combination of the above compounds. The I-III-VI group semiconductor compound may further include an II group element. For example, the I-III-VI group semiconductor compound may include a quaternary compound such as CuInZnS.

The first quantum dot QD1 and the second quantum dot QD2 may each independently have a homogeneous single structure or a composite structure such as a core-shell structure, a gradient structure, and/or the like.

Each of the first electron transport area ET1, the second electron transport area ET2, and the third electron transport area ET3 may have i) a single layer structure made of a single material, ii) a single layer structure made of a plurality of different materials, or iii) a multi-layer structure made of a plurality of different materials.

Each of the first electron transport area ET1, the second electron transport area ET2, and the third electron transport area ET3 may include at least one layer selected from among a buffer layer, a hole blocking layer, an electron control layer, an electron transport layer, and an electron injection layer. In one or more embodiments, the first electron transport area ET1, the second electron transport area ET2, and the third electron transport area ET3 may each independently include an amorphous inorganic material and/or an organic material.

Referring back to FIG. 2, the first common electrode CE1 may be located on the first intermediate layer ML1. The first common electrode CE1 may be located in at least a portion of the first through-hole. For example, the first common electrode CE1 may be located in a portion of the first opening of the second partition wall layer MT2. For example, the first common electrode CE1 may be located in the first pixel area PX1.

The second common electrode CE2 may be located on the second intermediate layer ML2. The second common electrode CE2 may be located in at least a portion of the second through-hole. For example, the second common electrode CE2 may be located in a portion of the second opening of the second partition wall layer MT2. For example, the second common electrode CE2 may be located in the second pixel area PX2.

The third common electrode CE3 may be located on the third intermediate layer ML3. The third common electrode CE3 may be located in at least a portion of the third through-hole. For example, the third common electrode CE3 may be located in a portion of the third opening of the second partition wall layer MT2. For example, the third common electrode CE3 may be located in the third pixel area PX3.

For example, the first common electrode CE1, the second common electrode CE2, and the third common electrode CE3 may each independently include a metal, an alloy, a metal nitride, a conductive metal oxide, a transparent conductive material, and/or the like. These materials may be used alone or in combination with each other. For example, each of the first common electrode CE1 and the second common electrode CE2 may be referred to as a third electrode. The third common electrode CE3 may be referred to as a fourth electrode.

The first resin layer RSL1 may be located on the first common electrode CE1. The first resin layer RSL1 may be located in at least a portion of the first through-hole. For example, the first resin layer RSL1 may be located in a portion of the first opening of the second partition wall layer MT2. However, this disclosure is not limited thereto, and the first resin layer RSL1 may also be located in a portion of the first opening of the third partition wall layer MT3. In one or more embodiments, the first resin layer RSL1 may contact at least a portion of the third partition wall layer MT3. For example, the first resin layer RSL1 may contact the first tip PT1. For example, the first resin layer RSL1 may contact a lower surface of the first tip PT1. However, this disclosure is not limited thereto, and in some embodiments, the first resin layer RSL1 may be spaced apart from the first tip PT1 in a direction opposite to the third direction DR3.

The second resin layer RSL2 may be located on the second common electrode CE2. The second resin layer RSL2 may be located in at least a portion of the second through-hole. For example, the second resin layer RSL2 may be located in a portion of the second opening of the second partition wall layer MT2. However, this disclosure is not limited thereto, and the second resin layer RSL2 may also be located in a portion of the second opening of the third partition wall layer MT3. In one or more embodiments, the second resin layer RSL2 may contact at least a portion of the third partition wall layer MT3. For example, the second resin layer RSL2 may contact the second tip PT2. For example, the second resin layer RSL2 may contact a lower surface of the second tip PT2. However, this disclosure is not limited thereto, and in some embodiments, the second resin layer RSL2 may be spaced apart from the second tip PT2 in a direction opposite to the third direction DR3.

The first resin layer RSL1 may overlap the first light emitting element LED1 in the plan view, and may be spaced apart from the third light emitting element LED3 in the plan view. For example, the first resin layer RSL1 may be located in the first pixel area PX1, and may be spaced apart from the third pixel area PX3 in the plan view. As described above, the first light emitting element LED1 may be a quantum dot light emitting element, and the third light emitting element LED3 may be an organic light emitting element. The first resin layer RSL1 may selectively overlap the quantum dot light emitting element (i.e., the first light emitting element LED1) in the plan view, and may be spaced apart from the organic light emitting element (i.e., the third light emitting element LED3) in the plan view.

For example, the first resin layer RSL1 may overlap the first intermediate layer ML1 in the plan view and may be spaced apart from the third intermediate layer ML3 in the plan view. For example, the first resin layer RSL1 may overlap the first light emitting layer (e.g., the first light emitting layer EML1 of FIG. 3) in the plan view and may be spaced apart from the third light emitting layer (e.g., the third light emitting layer EML3 of FIG. 3) in the plan view.

The second resin layer RSL2 may overlap the second light emitting element LED2 in the plan view, and may be spaced apart from the third light emitting element LED3 in the plan view. For example, the second resin layer RSL2 may be located in the second pixel area PX2, and may be spaced apart from the third pixel area PX3 in the plan view. As described above, the second light emitting element LED2 may be a quantum dot light emitting element, and the third light emitting element LED3 may be an organic light emitting element. The second resin layer RSL2 may selectively overlap the quantum dot light emitting element (i.e., the second light emitting element LED2) in the plan view, and may be spaced apart from the organic light emitting element (i.e., the third light emitting element LED3) in the plan view.

For example, the second resin layer RSL2 may overlap the second intermediate layer ML2 in the plan view, and may be spaced apart from the third intermediate layer ML3 in the plan view. For example, the second resin layer RSL2 may overlap the second light emitting layer (e.g., the second light emitting layer EML2 of FIG. 3) in the plan view, and may be spaced apart from the third light emitting layer (e.g., the third light emitting layer EML3 of FIG. 3) in the plan view.

In one or more embodiments, each of the first resin layer RSL1 and the second resin layer RSL2 may include a resin and an active component. Examples of the resin may include a photoresist, a polyacryl-based resin, a polyimide-based resin, a polyamide-based resin, a siloxane-based resin, an acrylic-based resin, an epoxy-based resin, and/or the like. These materials may be used alone or in combination with each other.

The active component may include an acid. For example, the active component may include acrylic acid, acetic acid, formic acid, propionic acid, butyric acid, isobutyric acid, valeric acid, ethylmethyl acetic acid, trimethyl acetic acid, succinic acid, adipic acid, citric acid, oxalic acid, lactic acid, tartaric acid, malic acid, ascorbic acid, malonic acid, carboxylic acid, and/or the like. These materials may be used alone or in combination with each other.

The active component of the first resin layer RSL1 may be diffused into the first light emitting element LED1. For example, the first light emitting element LED1 may include the active component diffused from the first resin layer RSL1. The active component may promote a positive aging effect (e.g., aspect) of the first light emitting element LED1 which is a quantum dot light emitting element.

The active component of the second resin layer RSL2 may be diffused into the second light emitting element LED2. For example, the second light emitting element LED2 may include the active component diffused from the second resin layer RSL2. The active component may promote a positive aging effect (e.g., aspect) of the second light emitting element LED2, which is a quantum dot light emitting element.

In a display device having a hybrid structure including a quantum dot light emitting element and an organic light emitting element, if (e.g., when) the active component is diffused into an organic light emitting element, characteristics of the organic light emitting element may be deteriorated unlike those of the quantum dot light emitting element.

According to one or more embodiments, the first resin layer RSL1 may selectively overlap the first light emitting element LED1 in the plan view and may be spaced apart from the third light emitting element LED3 in the plan view by the bank layer BK. For example, the first resin layer RSL1 may selectively overlap the first light emitting element LED1 in the plan view and may be spaced apart from the third light emitting element LED3 in the plan view by the second partition wall layer MT2. In addition, the second resin layer RSL2 may selectively overlap the second light emitting element LED2 in the plan view and may be spaced apart from the third light emitting element LED3 in the plan view by the bank layer BK. For example, the second resin layer RSL2 may selectively overlap the second light emitting element LED2 in the plan view and may be spaced apart from the third light emitting element LED3 in the plan view by the second partition wall layer MT2.

As a result, the active component from the first resin layer RSL1 may be selectively diffused into the first light emitting element LED1 which is a quantum dot light emitting element, and may not affect (or may not substantively affect) the third light emitting element LED3 which is an organic light emitting element. In one or more embodiments, the active component from the second resin layer RSL2 may be selectively diffused into the second light emitting element LED2 which is a quantum dot light emitting element, and may not affect (or may not substantively affect) the third light emitting element LED3 which is an organic light emitting element. Accordingly, a positive aging effect (e.g., aspect) of the quantum dot light emitting element may be promoted, and a characteristic degradation of the organic light emitting element may be prevented or reduced. Accordingly, characteristics of the display device DD may be improved.

In one or more embodiments, the display device DD may further include a first capping layer between the first common electrode CE1 and the first resin layer RSL1. The first capping layer may protect the first common electrode CE1 and enhance light extraction efficiency. In one or more embodiments, the display device DD may further include a second capping layer between the second common electrode CE2 and the second resin layer RSL2. The second capping layer may protect the second common electrode CE2 and enhance light extraction efficiency. In one or more embodiments, the display device DD may further include a third capping layer on the third common electrode CE3. The third capping layer may protect the third common electrode CE3 and enhance light extraction efficiency. For example, the first capping layer, the second capping layer, and the third capping layer may each independently include an organic material, and may also include an inorganic material such as LiF.

The encapsulation layer TFE may be located on the third partition wall layer MT3. For example, the encapsulation layer TFE may cover at least a portion of the third partition wall layer MT3. In one or more embodiments, the encapsulation layer TFE may cover at least a portion of each of the first resin layer RSL1, the second resin layer RSL2, and the third common electrode CE3. For example, the encapsulation layer TFE may include at least one inorganic encapsulation layer and at least one organic encapsulation layer. For example, the inorganic encapsulation layer may include silicon oxide, silicon nitride, silicon oxynitride, and/or the like, and the organic encapsulation layer may include a cured polymer such as polyacrylate.

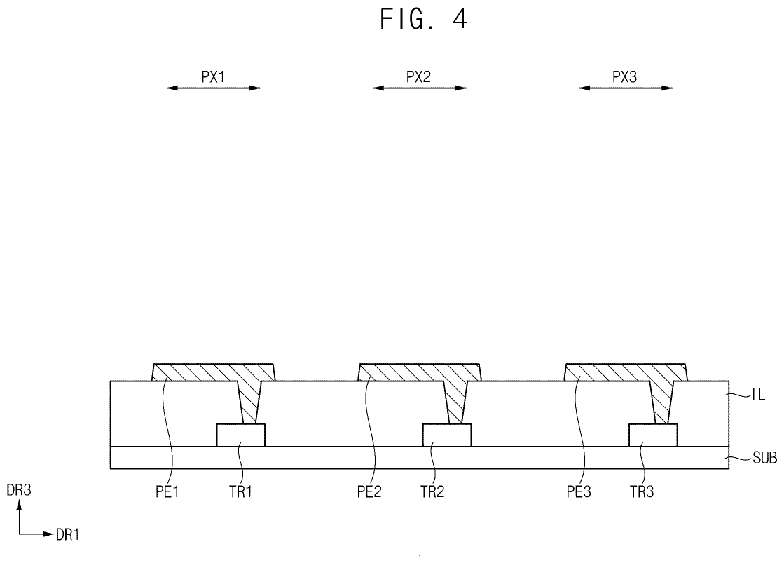

FIGS. 4, 5, 6, 7, 8, 9, 10, and 11 are cross-sectional views illustrating a method of manufacturing the display device of FIG. 2.

Referring to FIG. 4, the first transistor TR1, the second transistor TR2, and the third transistor TR3 may be formed on a substrate SUB. In one or more embodiments, the insulating structure IL may be formed on the substrate SUB. The insulating structure IL may be formed to cover the first transistor TR1, the second transistor TR2, and the third transistor TR3.

The first contact hole for connecting the first pixel electrode PE1 and the first transistor TR1 may be formed in the insulating structure IL. The second contact hole for connecting the second pixel electrode PE2 and the second transistor TR2 may be formed in the insulating structure IL. The third contact hole for connecting the third pixel electrode PE3 and the third transistor TR3 may be formed in the insulating structure IL.

The first pixel electrode PE1, the second pixel electrode PE2, and the third pixel electrode PE3 may be formed on the insulating structure IL. The first pixel electrode PE1 may be formed in the first pixel area PX1, the second pixel electrode PE2 may be formed in the second pixel area PX2, and the third pixel electrode PE3 may be formed in the third pixel area PX3.

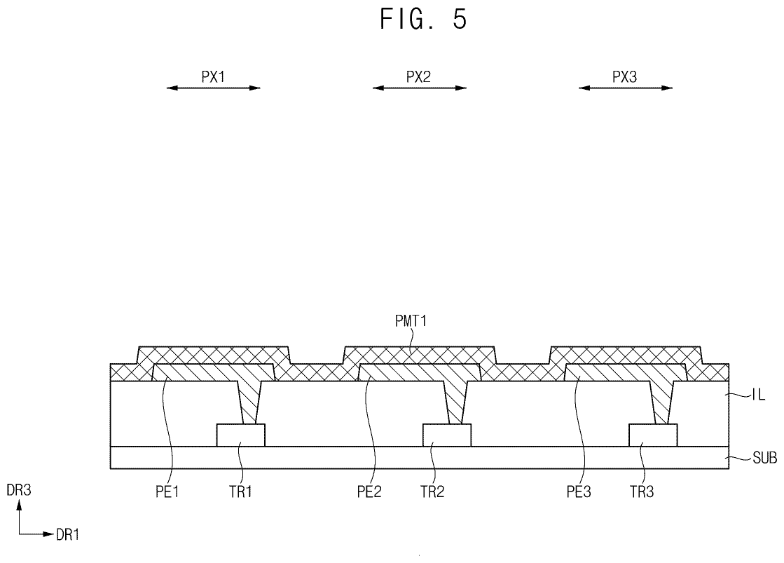

Referring to FIG. 5, a first preliminary partition wall layer PMT1 may be formed on the insulating structure IL. The first preliminary partition wall layer PMT1 may be formed to cover the first pixel electrode PE1, the second pixel electrode PE2, and the third pixel electrode PE3. In one or more embodiments, the first preliminary partition wall layer PMT1 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. In one or more embodiments, examples of the metal nitride may include aluminum nitride (“AlNₓ”), tungsten nitride (“WNₓ”), chromium nitride (“CrNₓ”), and/or the like. These materials may be used alone or in combination with each other. For example, each of the first partition wall layer MT1 and the third partition wall layer MT3 may include titanium (“Ti”), and the second partition wall layer MT2 may include aluminum (“Al”). For example, the first preliminary partition wall layer PMT1 may include titanium (“Ti”). However, this disclosure is not limited thereto, and in some embodiments, the first preliminary partition wall layer PMT1 may include an inorganic material and/or an organic material. For example, the first preliminary partition wall layer PMT1 may include an inorganic material.

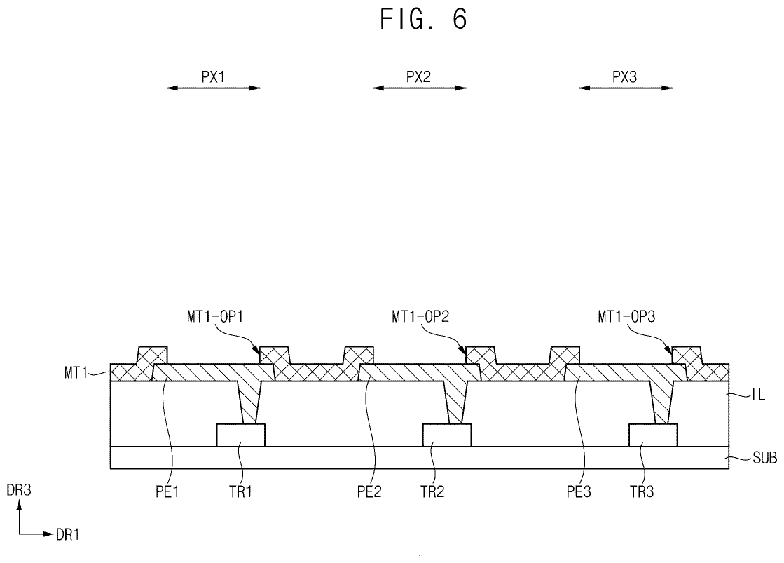

Referring to FIGS. 5 and 6, a portion of the first preliminary partition wall layer PMT1 may be removed. For example, a first opening MT1-OP1, a second opening MT1-OP2, and a third opening MT1-OP3 may be formed in the first preliminary partition wall layer PMT1. The first opening MT1-OP1 may be formed in the first pixel area PX1, the second opening MT1-OP2 may be formed in the second pixel area PX2, and the third opening MT1-OP3 may be formed in the third pixel area PX3. Accordingly, the first partition wall layer MT1 may be formed.

In one or more embodiments, the first opening MT1-OP1, the second opening MT1-OP2, and the third opening MT1-OP3 may be formed by a dry etching process. For example, after a photoresist film is applied on the first preliminary partition wall layer PMT1, the photoresist film may be exposed and developed using an exposure mask and/or the like. Accordingly, a photoresist pattern may be formed on the first preliminary partition wall layer PMT1. Using the photoresist pattern as a mask, a portion of the first preliminary partition wall layer PMT1 may be removed. Accordingly, the first partition wall layer MT1 defining the first opening MT1-OP1, the second opening MT1-OP2, and the third opening MT1-OP3 may be formed. Thereafter, the photoresist pattern may be removed. However, this disclosure is not limited thereto, and a method of forming the first opening MT1-OP1, the second opening MT1-OP2, and the third opening MT1-OP3 may be variously suitably changed according to one or more embodiments.

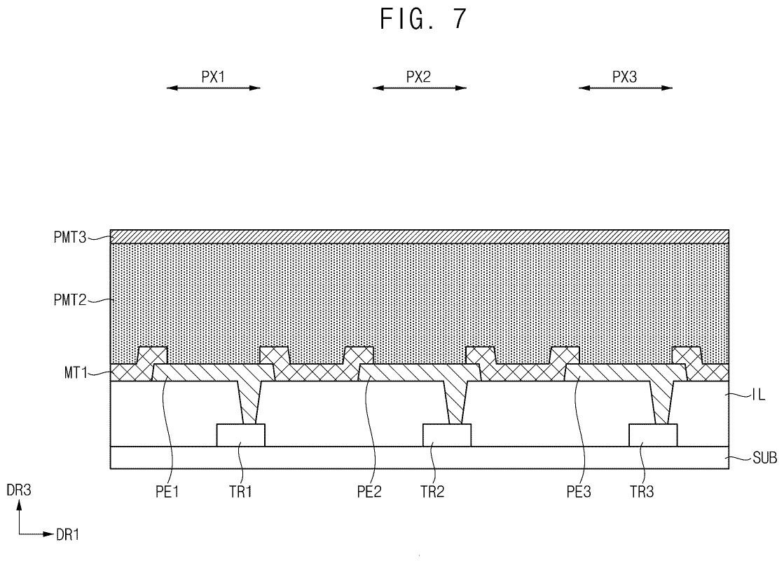

Referring to FIG. 7, a second preliminary partition wall layer PMT2 may be formed on the first partition wall layer MT1. The second preliminary partition wall layer PMT2 may be formed to cover at least a portion of each of the first partition wall layer MT1, the first pixel electrode PE1, the second pixel electrode PE2, and the third pixel electrode PE3. In one or more embodiments, the second preliminary partition wall layer PMT2 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. In one or more embodiments, examples of the metal nitride may include aluminum nitride (“AlNₓ”), tungsten nitride (“WNₓ”), chromium nitride (“CrNₓ”), and/or the like. These materials may be used alone or in combination with each other. For example, each of the first partition wall layer MT1 and the third partition wall layer MT3 may include titanium (“Ti”), and the second partition wall layer MT2 may include aluminum (“Al”). For example, the second preliminary partition wall layer PMT2 may include aluminum (“Al”). However, this disclosure is not limited thereto, and in some embodiments, the second preliminary partition wall layer PMT2 may include an inorganic material and/or an organic material. For example, the second preliminary partition wall layer PMT2 may include an organic material.

A third preliminary partition wall layer PMT3 may be formed on the second preliminary partition wall layer PMT2. The third preliminary partition wall layer PMT3 may be formed to cover the second preliminary partition wall layer PMT2. In one or more embodiments, the third preliminary partition wall layer PMT3 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. In one or more embodiments, examples of the metal nitride may include aluminum nitride (“AlNₓ”), tungsten nitride (“WNₓ”), chromium nitride (“CrNₓ”), and/or the like. These materials may be used alone or in combination with each other. For example, each of the first partition wall layer MT1 and the third partition wall layer MT3 may include titanium (“Ti”), and the second partition wall layer MT2 may include aluminum (“Al”). For example, the third preliminary partition wall layer PMT3 may include titanium (“Ti”). However, this disclosure is not limited thereto, and in some embodiments, the third preliminary partition wall layer PMT3 may include an inorganic material and/or an organic material. For example, the third preliminary partition wall layer PMT3 may include an inorganic material.

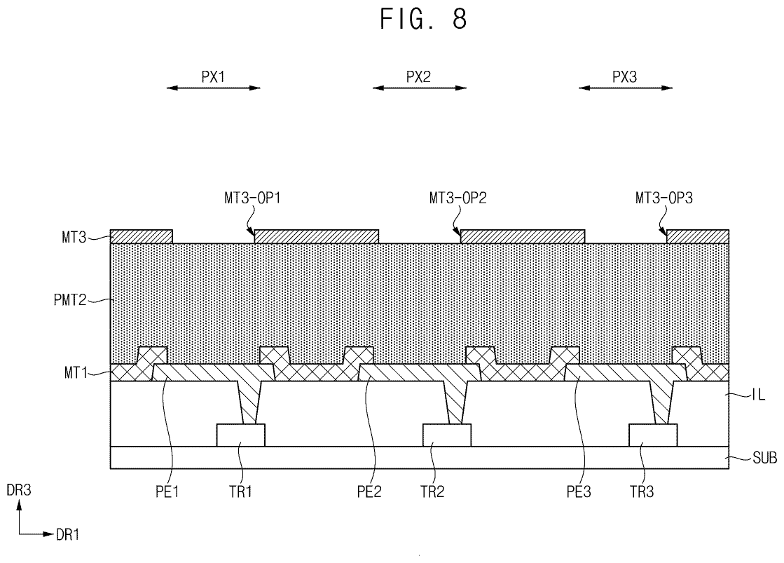

Referring to FIGS. 7 and 8, a portion of the third preliminary partition wall layer PMT3 may be removed. For example, a first opening MT3-OP1, a second opening MT3-OP2, and a third opening MT3-OP3 may be formed in the third preliminary partition wall layer PMT3. The first opening MT3-OP1 may be formed in the first pixel area PX1, the second opening MT3-OP2 may be formed in the second pixel area PX2, and the third opening MT3-OP3 may be formed in the third pixel area PX3. Accordingly, the third partition wall layer MT3 may be formed.

In one or more embodiments, the first opening MT3-OP1, the second opening MT3-OP2, and the third opening MT3-OP3 may be formed by a dry etching process. For example, after a photoresist film is applied on the third preliminary partition wall layer PMT3, the photoresist film may be exposed and developed using an exposure mask and/or the like. Accordingly, a photoresist pattern may be formed on the third preliminary partition wall layer PMT3. Using the photoresist pattern as a mask, a portion of the third preliminary partition wall layer PMT3 may be removed. Accordingly, a third partition wall layer MT3 defining the first opening MT3-OP1, the second opening MT3-OP2, and the third opening MT3-OP3 may be formed. Thereafter, the photoresist pattern may be removed. However, this disclosure is not limited thereto, and a method of forming the first opening MT3-OP1, the second opening MT3-OP2, and the third opening MT3-OP3 may be variously suitably changed according to one or more embodiments.

Referring to FIGS. 8 and 9, a portion of the second preliminary partition wall layer PMT2 may be removed. For example, a first opening MT2-OP1, a second opening MT2-OP2, and a third opening MT2-OP3 may be formed in the second preliminary partition wall layer PMT2. The first opening MT2-OP1 is formed in the first pixel area PX1, the second opening MT2-OP2 is formed in the second pixel area PX2, and the third opening MT2-OP3 may be formed in the third pixel area PX3. Accordingly, the second partition wall layer MT2 may be formed.

In one or more embodiments, the first opening MT2-OP1, the second opening MT2-OP2, and the third opening MT2-OP3 may be formed by a wet etching process. For example, the first partition wall layer MT1 and the third partition wall layer MT3 may include titanium (“Ti”), and the second preliminary partition wall layer PMT2 may include aluminum (“Al”). In terms of etching selectivity, an etching rate of the aluminum metal layer may be greater than an etching rate of the titanium metal layer. Accordingly, through the wet etching process, the first partition wall layer MT1 and the third partition wall layer MT3 may be hardly removed (e.g., may not be substantially removed), or only a portion significantly smaller than a portion of the second preliminary partition wall layer PMT2 may be removed. Accordingly, a structure in which the third partition wall layer MT3 includes the first tip (e.g., the first tip PT1 of FIG. 2), the second tip (e.g., the second tip PT2 of FIG. 2), and the third tip (e.g., the third tip PT3 of FIG. 2) may be formed. However, this disclosure is not limited thereto, and a method of forming the first opening MT2-OP1, the second opening MT2-OP2, and the third opening MT2-OP3 may be variously suitably changed according to one or more embodiments.

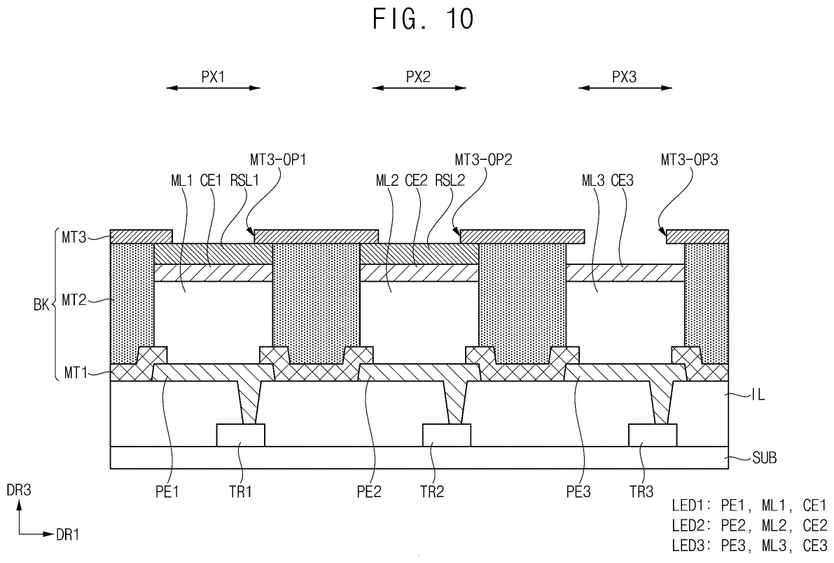

In one or more embodiments, a method of manufacturing the display device (e.g., the display device DD of FIG. 2) according to one or more embodiments may further include a step (e.g., act or task) of plasma-treating to at least a portion of the bank layer BK before the first intermediate layer (e.g., the first intermediate layer ML1 of FIG. 10), the second intermediate layer (e.g., the second intermediate layer ML2 of FIG. 10), and the third intermediate layer (e.g., the third intermediate layer ML3 of FIG. 10) are formed. For example, an upper surface of the third partition wall layer MT3 may be subjected to CF₄ plasma treatment. Accordingly, water repellency may be applied to the upper surface of the third partition wall layer MT3, and when the first intermediate layer, the second intermediate layer, the third intermediate layer, the first resin layer (e.g., the first resin layer RSL1 of FIG. 10), the second resin layer (e.g., the second resin layer of FIG. 10), and/or the like are formed, the formation of the first intermediate layer, the third intermediate layer, the first resin layer, the second resin layer, and/or the like up to the upper surface of the third partition wall layer MT3 may be prevented or reduced.

Referring to FIGS. 9 and 10, the first intermediate layer ML1 may be formed on the first pixel electrode PE1. The first intermediate layer ML1 may be formed in a portion of the first opening MT2-OP1 of the second partition wall layer MT2 and in the first opening MT1-OP1 of the first partition wall layer MT1. In one or more embodiments, the first intermediate layer ML1 may be formed through an inkjet printing process.

For example, a first quantum dot composition may be provided through an inkjet printing process in a portion of the first opening MT2-OP1 of the second partition wall layer MT2 and in the first opening MT1-OP1 of the first partition wall layer MT1. The first quantum dot composition may be a material for forming the first light emitting layer (e.g., the first light emitting layer EML1 of FIG. 3). For example, the first quantum dot composition may include an inorganic light emitting material including a solvent and the first quantum dot (e.g., the first quantum dot QD1 of FIG. 3).

The second intermediate layer ML2 may be formed on the second pixel electrode PE2. The second intermediate layer ML2 may be formed in a portion of the second opening MT2-OP2 of the second partition wall layer MT2 and in the second opening MT1-OP2 of the first partition wall layer MT1. In one or more embodiments, the second intermediate layer ML2 may be formed through an inkjet printing process. For example, a second quantum dot composition may be provided through an inkjet printing process in a portion of the second opening MT2-OP2 of the second partition wall layer MT2 and the second opening MT1-OP2 of the first partition wall layer MT1. The second quantum dot composition may be a material for forming the second light emitting layer (e.g., the second light emitting layer EML2 of FIG. 3). For example, the second quantum dot composition may include an inorganic light emitting material including a solvent and the second quantum dot (e.g., the second quantum dot QD2 of FIG. 3).

The third intermediate layer ML3 may be formed on the third pixel electrode PE3. The third intermediate layer ML3 may be formed in a portion of the third opening MT2-OP3 of the second partition wall layer MT2 and in the third opening MT1-OP3 of the first partition wall layer MT1. In one or more embodiments, the third intermediate layer ML3 may be formed through an inkjet printing process.

For example, an organic composition may be provided through an inkjet printing process in a portion of the third opening MT2-OP3 of the second partition wall layer MT2 and in the third opening MT1-OP3 of the first partition wall layer MT1. The organic composition may include a material for forming the third light emitting layer (for example, the third light emitting layer EML3 of FIG. 3). For example, the organic composition may include a solvent and an organic light emitting material.

Thereafter, the first quantum dot composition, the second quantum dot composition, and the organic composition may be dried and/or heat-treated to form the first light emitting layer, the second light emitting layer, and the third light emitting layer, respectively.

The first hole transport area HL1, the second hole transport area HL2, the third hole transport area HL3, the first electron transport area ET1, the second electron transport area ET2, and the third electron transport area ET3 described with reference to FIG. 3 may be formed through an inkjet printing process. However, this disclosure is not limited thereto, and a method of forming the first hole transport area HL1, the second hole transport area HL2, the third hole transport area HL3, the first electron transport area ET1, the second electron transport area ET2, and the third electron transport area ET3 may be variously suitably changed according to one or more embodiments.

According to the present embodiments, the third partition wall layer MT3 may include the first tip (e.g., the first tip PT1 of FIG. 2). Accordingly, when the first intermediate layer ML1 is formed through the inkjet printing process, a thickness of the first intermediate layer ML1 may be relatively (e.g., substantially) uniform. For example, when the first intermediate layer ML1 is formed through the inkjet printing process, a thickness of an edge portion of the first intermediate layer ML1 may be relatively (e.g., substantially) uniform.

In one or more embodiments, the third partition wall layer MT3 may include the second tip (e.g., the second tip PT2 of FIG. 2). Accordingly, when the second intermediate layer ML2 is formed through the inkjet printing process, a thickness of the second intermediate layer ML2 may be relatively (e.g., substantially) uniform. For example, when the second intermediate layer ML2 is formed through the inkjet printing process, a thickness of an edge portion of the second intermediate layer ML2 may be relatively (e.g., substantially) uniform.

In one or more embodiments, the third partition wall layer MT3 may include the third tip (for example, the third tip PT3 of FIG. 2). Accordingly, when the third intermediate layer ML3 is formed through the inkjet printing process, a thickness of the third intermediate layer ML3 may be relatively (e.g., substantially) uniform. For example, when the third intermediate layer ML3 is formed through the inkjet printing process, a thickness of an edge portion of the third intermediate layer ML3 may be relatively (e.g., substantially) uniform.

The first common electrode CE1 may be formed on the first intermediate layer ML1. The first common electrode CE1 may be formed in the first opening MT2-OP1 of the second partition wall layer MT2. Accordingly, the first light emitting element LED1 including the first pixel electrode PE1, the first intermediate layer ML1, and the first common electrode CE1 may be formed.

The second common electrode CE2 may be formed on the second intermediate layer ML2. The second common electrode CE2 may be formed in the second opening MT2-OP2 of the second partition wall layer MT2. Accordingly, the second light emitting element LED2 including the second pixel electrode PE2, the second intermediate layer ML2, and the second common electrode CE2 may be formed.

The third common electrode CE3 may be formed on the third intermediate layer ML3. The third common electrode CE3 may be formed in the third opening MT2-OP3 of the second partition wall layer MT2. Accordingly, the third light emitting element LED3 including the third pixel electrode PE3, the third intermediate layer ML3, and the third common electrode CE3 may be formed.

The first resin layer RSL1 may be formed on the first common electrode CE1. The first resin layer RSL1 may be formed in the first opening MT2-OP1 of the second partition wall layer MT2. In one or more embodiments, the first resin layer RSL1 may be formed through an inkjet printing process. For example, the third partition wall layer MT3 may include the first tip. Accordingly, when the first resin layer RSL1 is formed through the inkjet printing process, a thickness of an edge portion of the first resin layer RSL1 may be relatively (e.g., substantially) uniform. However, this disclosure is not limited thereto, and a method of forming the first resin layer RSL1 may be variously suitably changed according to one or more embodiments.

The second resin layer RSL2 may be formed on the second common electrode CE2. The second resin layer RSL2 may be formed in the second opening MT2-OP2 of the second partition wall layer MT2. In one or more embodiments, the second resin layer RSL2 may be formed through an inkjet printing process. For example, the third partition wall layer MT3 may include the second tip. Accordingly, when the second resin layer RSL2 is formed through the inkjet printing process, a thickness of an edge portion of the second resin layer RSL2 may be relatively (e.g., substantially) uniform. However, this disclosure is not limited thereto, and the method of forming the second resin layer RSL2 may be variously suitably changed according to one or more embodiments.

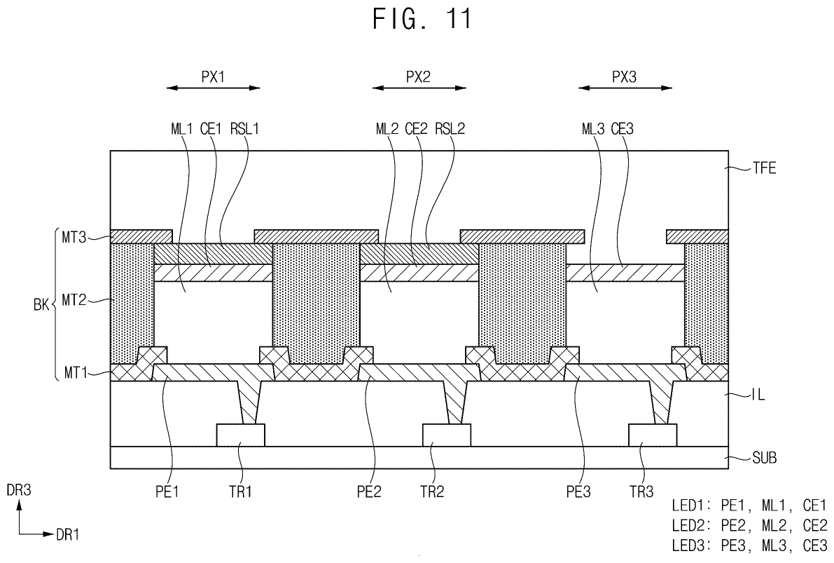

Referring to FIG. 11, the encapsulation layer TFE may be formed on the third partition wall layer MT3. For example, the encapsulation layer TFE may be formed to cover at least a portion of the third partition wall layer MT3. In one or more embodiments, the encapsulation layer TFE may be formed to cover at least a portion of each of the first resin layer RSL1, the second resin layer RSL2, and the third common electrode CE3.

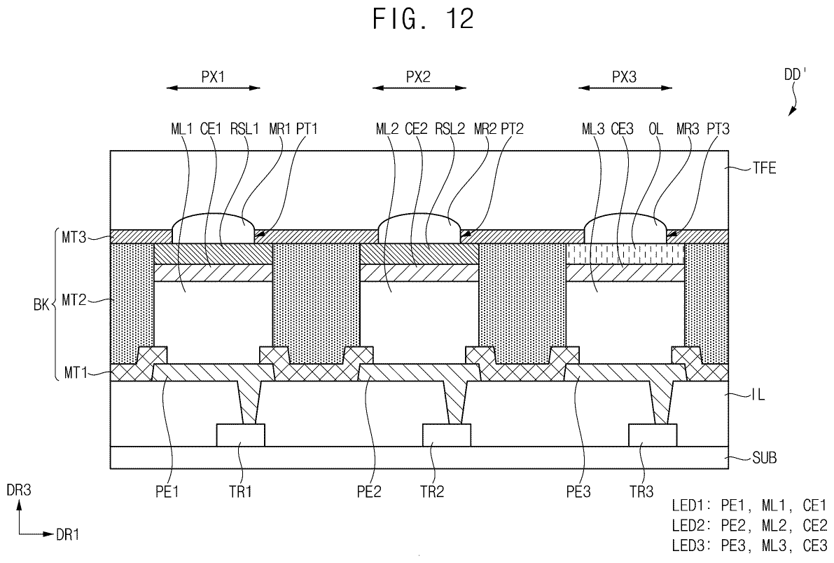

FIG. 12 is a cross-sectional view illustrating a display device according to one or more other embodiments. For example, the cross-sectional view of FIG. 12 may correspond to the cross-sectional view of FIG. 2 (e.g., the cross-sectional view of FIG. 12 may illustrate a cross-section taken along the line I-I′ of FIG. 1).

The display device DD′ according to one or more embodiments described with reference to FIG. 12 may be substantially the same as or similar to the display device DD described with reference to FIG. 2 except for configurations of a first lens layer MR1, a second lens layer MR2, a third lens layer MR3, and a step compensation layer OL. Accordingly, redundant descriptions are not provided or are simplified.

Referring to FIG. 12, a display device DD′ according to one or more embodiments may include the substrate SUB, the insulating structure IL, the first transistor TR1, the second transistor TR2, the third transistor TR3, the first light emitting element LED1, the second light emitting element LED2, the third light emitting element LED3, the first resin layer RSL1, the second resin layer RSL2, the bank layer BK, a first lens layer MR1, a second lens layer MR2, a third lens layer MR3, a step compensation layer OL, and the encapsulation layer TFE.

The first lens layer MR1 may be located on the first resin layer RSL1. For example, the first lens layer MR1 may cover the first resin layer RSL1. The first lens layer MR1 may be located in the first pixel area PX1. The first lens layer MR1 may increase efficiency and/or intensity of light emitted from the first light emitting element LED1. For example, the first lens layer MR1 may include an oxide, a nitride, a silicon compound, a polymer organic material, and/or the like. These materials may be used alone or in combination with each other. However, this disclosure is not limited thereto, and materials included in the first lens layer MR1 may be variously suitably changed according to one or more embodiments.

The second lens layer MR2 may be located on the second resin layer RSL2. For example, the second lens layer MR2 may cover the second resin layer RSL2. The second lens layer MR2 may be located in the second pixel area PX2. The second lens layer MR2 may increase efficiency and/or intensity of light emitted from the second light emitting element LED2. For example, the second lens layer MR2 may include an oxide, a nitride, a silicon compound, a polymer organic material, and/or the like. These materials may be used alone or in combination with each other. However, this disclosure is not limited thereto, and materials included in the second lens layer MR2 may be variously suitably changed according to one or more embodiments.

The step compensation layer OL may be located on the third common electrode CE3. Here, a resin layer including an active ingredient may not be located in the third pixel area PX3. Accordingly, the third lens layer MR3 may be directly located on the third common electrode CE3. In this case, the third lens layer MR3 may be located at a different level from a level of the first lens layer MR1 and the second lens layer MR2. In this specification, “A is located at a different level of B” may refer to a vertical distance from an upper surface of the substrate SUB to A and a vertical distance from the upper surface of the substrate SUB to B being different. According to one or more embodiments, as the step compensation layer OL is located on the third common electrode CE3, the third lens layer MR3 located on the step compensation layer OL may be located at substantially same level as the first lens layer MR1 and the second lens layer MR2. For example, the step compensation layer OL may include an organic material, but this disclosure is not limited thereto.

The third lens layer MR3 may be located on the step compensation layer OL. For example, the third lens layer MR3 may cover the step compensation layer OL. The third lens layer MR3 may be located in the third pixel area PX3. The third lens layer MR3 may increase efficiency and/or intensity of light emitted from the third light emitting device LED3. For example, the third lens layer MR3 may include an oxide, a nitride, a silicon compound, a polymer organic material, and/or the like. These materials may be used alone or in combination with each other. However, this disclosure is not limited thereto, and materials included in the third lens layer MR3 may be variously suitably changed according to one or more embodiments.

The encapsulation layer TFE may be located on the third partition wall layer MT3. The encapsulation layer TFE may cover at least a portion of the third partition wall layer MT3. In one or more embodiments, the encapsulation layer TFE may cover at least a portion of each of the first lens layer MR1, the second lens layer MR2, and the third lens layer MR3.

The display device (e.g., the display device DD of FIG. 1) according to one or more embodiments may be applied to one or more suitable electronic devices. An electronic device according to one or more embodiments may include the above-described display device, and may further include a module and/or device having other additional functions in addition to the display device.

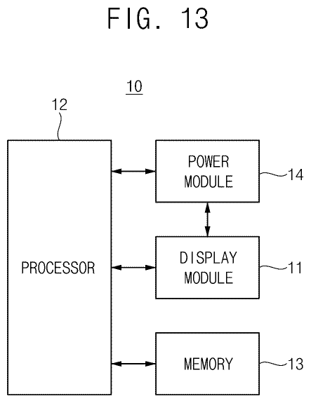

FIG. 13 is a block diagram illustrating an electronic device according to one or more embodiments.

Referring to FIG. 13, an electronic device 10 according to one or more embodiments may include a display module 11, a processor 12, a memory 13, and a power module 14.

The processor 12 may include at least one selected from among a central processing unit (“CPU”), an application processor (“AP”), a graphic processing unit (“GPU”), a communication processor (“CP”), an image signal processor (“ISP”), and a controller.

Data information necessary for operation of the processor 12 and/or the display module 11 may be stored in the memory 13. When the processor 12 executes an application stored in the memory 13, an image data signal and/or an input control signal is transmitted to the display module 11, and the display module 11 may process received signal and output image information through a display screen.

The power module 14 may include a power supply module such as a power adapter and/or a battery device, and a power conversion module that converts power supplied by the power supply module to generate power desired or required for operation of the electronic device 10.

At least one of components of the electronic device 10 described above may be included in the display device according to the above-described embodiments. In one or more embodiments, some of individual modules functionally included in one module may be included in the display device, and others may be provided separately from the display device. For example, the display device may include the display module 11, and the processor 12, the memory 13, and the power module 14 may be provided in form of another device in the electronic device 10 other than the display device.

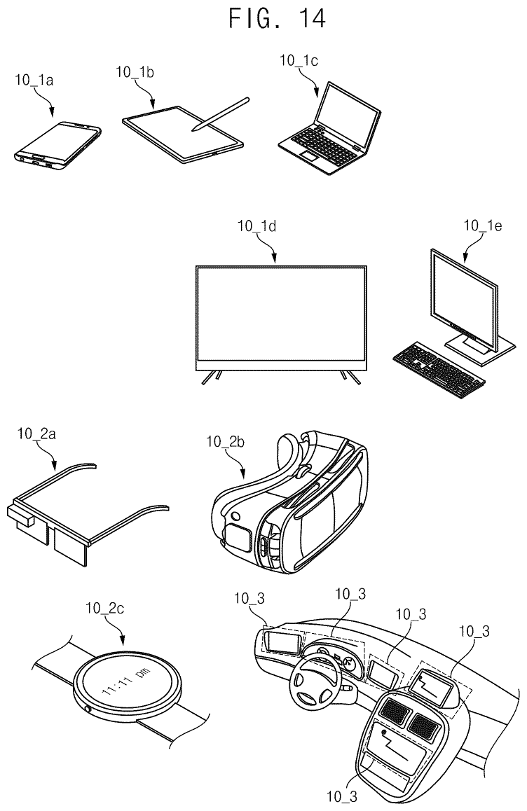

FIG. 14 is a schematic diagram of electronic devices according to one or more suitable embodiments.

Referring to FIG. 14, one or more suitable electronic devices to which display devices according to one or more embodiments are applied may include electronic devices for image display such as a smartphone 10_1a, a tablet PC 10_1b, a laptop 10_1c, a TV 10_1d, a desk monitor 10_1e, and/or the like, wearable electronic devices including display modules such as a smart glass (or smart glasses) 10_2a, a head mounted display 10_2b, a smart watch 10_2c, and/or the like, and/or vehicle electronic device 10_3 including display modules such as a vehicle's instrument panel, a center fascia, a center information display (“CID”) located on a dashboard, a room mirror display, and/or the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present disclosure. Accordingly, all such modifications are intended to be included within the scope of the present disclosure as defined in the claims and their equivalents. Therefore, it is to be understood that the foregoing is illustrative of one or more suitable embodiments and is not to be construed as limited to the specific embodiments disclosed herein, and that modifications to the disclosed embodiments, as well as other embodiments, are intended to be included within the scope of the appended claims and their equivalents.

What is claimed is:

1. A display device comprising:
a first electrode in a first pixel area;
a second electrode in a second pixel area spaced apart from the first pixel area in a plan view;
a first partition wall layer on the first electrode and defining a first opening in the first pixel area and a second opening in the second pixel area;
a first intermediate layer in the first opening and comprising an inorganic light emitting material;
a third electrode on the first intermediate layer in the first opening;
a resin layer on the third electrode in the first opening;
a second intermediate layer in the second opening and comprising an organic light emitting material; and
a fourth electrode on the second intermediate layer in the second opening.

2. The display device of claim 1, wherein the resin layer is spaced apart from the second pixel area in the plan view.

3. The display device of claim 1, wherein the second intermediate layer is to emit blue light.

4. The display device of claim 1, wherein the first intermediate layer comprises,
a first hole transport area;
a first light emitting layer on the first hole transport area and comprising an inorganic light emitting material; and
a first electron transport area on the first light emitting layer.

5. The display device of claim 4, wherein the second intermediate layer comprises,
a second hole transport area;
a second light emitting layer on the second hole transport area and comprising an organic light emitting material; and
a second electron transport area on the second light emitting layer.

6. The display device of claim 1, further comprising:
a second partition wall layer on the first partition wall layer and comprising a first tip protruding from an upper surface of the first partition wall layer toward a center of the first opening.

7. The display device of claim 6, wherein the second partition wall layer further comprises a second tip protruding from the upper surface of the first partition wall layer toward a center of the second opening.

8. The display device of claim 6, wherein the resin layer contacts the first tip.

9. The display device of claim 1, wherein the resin layer comprises an active component comprising an acid.

10. The display device of claim 1, further comprising:
a step compensation layer on the fourth electrode in the second opening.

11. The display device of claim 10, further comprising:
a first lens layer covering the resin layer; and
a second lens layer covering the step compensation layer.

12. The display device of claim 11, further comprising:
an encapsulation layer covering the first lens layer and the second lens layer.

13. The display device of claim 1, wherein the first partition wall layer comprises a metal.

14. A method of manufacturing a display device, the method comprising:
forming a first electrode in a first pixel area;
forming a second electrode in a second pixel area spaced apart from the first pixel area in a plan view;
forming a first partition wall layer defining a first opening in the first pixel area and a second opening in the second pixel area on the first electrode;
forming a first intermediate layer comprising an inorganic light emitting material in the first opening;
forming a third electrode on the first intermediate layer in the first opening;
forming a resin layer on the third electrode in the first opening;
forming a second intermediate layer comprising an organic light emitting material in the second opening; and
forming a fourth electrode on the second intermediate layer in the second opening.

15. The method of claim 14, wherein the forming of the first partition wall layer comprises,
forming a first preliminary partition wall layer on the first electrode; and
forming the first opening and the second opening in the first preliminary partition wall layer through a wet etching process.

16. The method of claim 15, further comprising:
forming a second preliminary partition wall layer on the first preliminary partition wall layer after the forming of the first preliminary partition wall layer, before the forming of the first opening and the second opening.

17. The method of claim 16, further comprising:
forming a third opening in the second preliminary partition wall layer in the first pixel area and a fourth opening in the second preliminary partition wall layer in the second pixel area through a dry etching process after the forming of the second preliminary partition wall layer, before the forming of the first opening and the second opening.

18. The method of claim 16, wherein the resin layer is formed to be spaced apart from the second opening in the plan view.

19. The method of claim 14, wherein each of the first intermediate layer, the second intermediate layer, and the resin layer is formed through an inkjet printing process.

20. An electronic device comprising:
a first electrode in a first pixel area;
a second electrode in a second pixel area spaced apart from the first pixel area in a plan view;
a first partition wall layer on the first electrode and defining a first opening in the first pixel area and a second opening in the second pixel area;
a first intermediate layer in the first opening and comprising an inorganic light emitting material;
a third electrode on the first intermediate layer in the first opening;
a resin layer on the third electrode in the first opening;
a second intermediate layer in the second opening and comprising an organic light emitting material;
a fourth electrode on the second intermediate layer in the second opening; and
a memory configured to store data information.
